(19) United States
(12) Patent Application Publication
(10) Pub. No.: US 2024/0063109 A1
(43) Pub. Date: Feb. 22, 2024

(54) FLIP CHIP SEMICONDUCTOR PACKAGES

(71) Applicant: Samsung Electronics Co., Ltd., Suwon-si (KR)

(72) Inventor: Kyunglyul Lee, Suwon-si (KR)

(21) Appl. No.: 18/354,777

(22) Filed: Jul. 19, 2023

(30) Foreign Application Priority Data
Aug. 22, 2022 (KR) 10-2022-0104915

(51) Int. Cl. H01L 23/498; H01L 23/00; H01L 23/31

(52) U.S. Cl. CPC H01L 23/49838; H01L 23/49822; H01L 24/16; H01L 23/3128; H01L 2224/16227

(57) ABSTRACT

A flip chip semiconductor package includes a wiring substrate that includes a core layer and a lower protection layer on a lower surface of the core layer, a trench group that includes a plurality of trenches spaced apart from one another on the lower protection layer, a flip chip on the wiring substrate and the trench group, and a molding layer that is on the flip chip and the wiring substrate, and extends into the plurality of trenches.

### CROSS-REFERENCE TO RELATED APPLICATION

This application is based on and claims priority under 35 U.S.C. § 119 to Korean Patent Application No. 10-2022-0104915, filed on Aug. 22, 2022, in the Korean Intellectual Property Office, the disclosure of which is incorporated by reference herein in its entirety.

### BACKGROUND

The inventive concept relates to semiconductor packages, and more particularly, to flip chip semiconductor packages.

In flip chip semiconductor packages, a semiconductor chip is electrically connected with an upper surface of a wiring substrate through a plurality of internal solder balls (or internal bumps) and is electrically connected with an external device through a plurality of external solder balls on a lower surface of the wiring substrate. Flip chip semiconductor packages are finished by molding the semiconductor chip, electrically connected with the wiring substrate, as a molding layer. In flip chip semiconductor packages, it may be difficult to fill the molding layer into a region between the internal solder balls.

### SUMMARY

Aspects of the inventive concept provide flip chip semiconductor packages in which a molding layer may be easily filled between internal solder balls and an arrangement region, where external solder balls are arranged, of a lower surface of a wiring substrate may increase.

According to aspects of the inventive concept, there is provided a flip chip semiconductor package including a wiring substrate that includes a core layer and a lower protection layer on a lower surface of the core layer, a trench group that includes a plurality of trenches spaced apart from one another on the lower protection layer, a flip chip on the wiring substrate and the trench group, and a molding layer that is on the flip chip and the wiring substrate, and extends into the plurality of trenches.

According to aspects of the inventive concept, there is provided a flip chip semiconductor package including a wiring substrate that includes a core layer, a wiring layer on the core layer, an upper protection layer on the wiring layer, a lower protection layer on a lower surface of the core layer, and a plurality of internal wiring pads spaced apart from one another, a trench group that includes a plurality of trenches spaced apart from one another, the plurality of trenches being on the lower protection layer and at least partially penetrating the wiring layer and the core layer, a flip chip on the wiring layer, the upper protection layer, and the trench group, the flip chip including a plurality of internal solder balls spaced apart from one another and on the plurality of internal wiring pads, and a molding layer on the flip chip and the wiring substrate, the molding layer extending into the plurality of trenches, a region between respective ones of the plurality of internal wiring pads, and a region between respective ones of the plurality of internal solder balls.

According to aspects of the inventive concept, there is provided a flip chip semiconductor package including a wiring substrate that includes a core layer, a wiring layer on the core layer, an upper protection layer on the wiring layer, a lower protection layer on a lower surface of the core layer, an opening region in the upper protection layer, and a plurality of internal wiring pads spaced apart from one another in the opening region, a trench group that includes a plurality of trenches spaced apart from one another, the plurality of trenches being on the lower protection layer and at least partially penetrating the wiring layer and the core layer, a flip chip on the opening region and the trench group, the flip chip including a plurality of internal solder balls spaced apart from one another and electrically connected to the plurality of internal wiring pads, a molding layer on the flip chip and the wiring substrate, the molding layer extending into the plurality of trenches, a region between respective ones of the plurality of internal wiring pads, and a region between respective ones of the plurality of internal solder balls, a plurality of external wiring pads spaced apart from one another and insulated from one another by the lower protection layer, and a plurality of external solder balls electrically connected to the plurality of external wiring pads.

### BRIEF DESCRIPTION OF THE DRAWINGS

Embodiments will be more clearly understood from the following detailed description taken in conjunction with the accompanying drawings in which:

FIG. 1 is a cross-sectional view for describing a flip chip semiconductor package according to some embodiments;

FIG. 2 is a partially enlarged view of the flip chip semiconductor package of FIG. 1;

FIG. 3 is a layout view of the flip chip semiconductor package of FIGS. 1 and 2;

FIG. 4 is a plan view for describing a method of forming a molding layer of the flip chip semiconductor package of FIGS. 1 to 3;

FIGS. 5 to 7 are cross-sectional views for describing a method of forming the molding layer of the flip chip semiconductor package of FIGS. 1 to 3;

FIG. 8 is a cross-sectional view for describing a flip chip semiconductor package according to some embodiments;

FIG. 9 is a layout view of the flip chip semiconductor package of FIG. 8;

FIG. 10 is a cross-sectional view for describing a flip chip semiconductor package according to some embodiments;

FIG. 11 is a layout view of the flip chip semiconductor package of FIG. 10;

FIG. 12 is a cross-sectional view for describing a flip chip semiconductor package according to some embodiments;

FIG. 13 is a layout view of the flip chip semiconductor package of FIG. 12;

FIG. 14 is a cross-sectional view for describing a flip chip semiconductor package according to some embodiments;

FIG. 15 is a layout view of the flip chip semiconductor package of FIG. 14; and

FIGS. 16 to 22 are cross-sectional views for describing a method of manufacturing the flip chip semiconductor package of FIGS. 1 to 3.

### DETAILED DESCRIPTION OF THE EMBODIMENTS

Hereinafter, embodiments will be described in detail with reference to the accompanying drawings. The following embodiments may be implemented as any one embodiment, and the following embodiments may also be implemented by a combination of one or more embodiments. Therefore, it is not construed that the inventive concept is limited to one embodiment.

Herein, a singular form of elements may include a plural form unless another case is clearly designated in context.

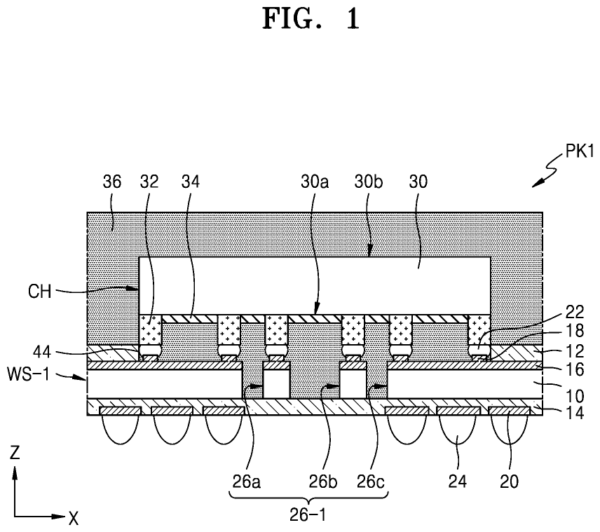

FIG. 1 is a cross-sectional view for describing a flip chip semiconductor package PK1 according to some embodiments.

In detail, the flip chip semiconductor package PK1 may include a wiring substrate WS-1, a core trench group 26-1, a flip chip CH, and a molding layer 36. FIG. 1 may be a cross-sectional view taken in a first direction (an X direction) and a third direction (a Z direction) with respect to a surface of the wiring substrate WS-1. The third direction may be a direction vertical to the surface of the wiring substrate WS-1.

The wiring substrate WS-1 may be a printed circuit board (PCB). The wiring substrate WS-1 may include a core layer 10 and a lower protection layer 14 which is formed on a lower surface of the core layer 10. The core layer 10 may include at least one of prepreg resin, thermo-curable epoxy resin, thermo-plastic epoxy resin, and/or filler-containing resin. As used herein, the term “and/or” includes any and all combinations of one or more of the associated listed items. The lower protection layer 14 may include a photosensitive resist (PSR).

The wiring substrate WS-1 may include a wiring layer 16, an upper protection layer 12, and internal wiring pads 18. The wiring layer 16 may be formed on the core layer 10. The wiring substrate WS-1 of FIG. 1 is illustrated as including one wiring layer 16, but is not limited thereto and may include a plurality of wiring layers. For example, the wiring layer 16 may be formed at a center portion of the core layer 10 or on a lower surface of the core layer 10. The upper protection layer 12 may be formed on the wiring layer 16. The upper protection layer 12 may include a PSR.

The internal wiring pads 18 may be spaced apart from one another. The wiring layer 16 and the internal wiring pads 18 may include a conductive material. The wiring layer 16 and the internal wiring pads 18 may include metal (for example, copper (Cu) or aluminum (Al)). The wiring substrate WS-1 may include an opening region 44 which is formed in the upper protection layer 12. The internal wiring pads 18 may be arranged apart from one another in the opening region 44 in the wiring layer 16.

A core trench group 26-1 may include a plurality of core trenches 26a to 26c which are spaced apart from one another on the lower protection layer 14. The core trench group 26-1 may be formed in the wiring layer 16 and the core layer 10, on the lower protection layer 14. The core trenches 26a to 26c may be arranged apart from one another at a center portion of the wiring substrate WS-1. For example, the core trenches 26a to 26c may extend into the wiring layer 16 and/or the core layer 10.

The flip chip CH may be disposed on the wiring substrate WS-1 and the core trench group 26-1. The flip chip CH may be disposed on the wiring layer 16, the upper protection layer 12, and the core trench group 26-1. The flip chip CH may be disposed on the opening region 44 and the core trench group 26-1. The opening region 44 may be an inner region of the upper protection layer 12. The opening region 44 may be a region where the wiring layer 16 and the internal wiring pads 18 are exposed by the upper protection layer 12.

The flip chip CH may include a chip body 30. The chip body 30 may include a first surface 30a and a second surface 30b. The first surface 30a (i.e., an upper surface) may be an active surface where a circuit layer is formed. For example, although the first surface 30a is illustrated as a lower surface in FIG. 1, the first surface 30a may be an upper surface of the flip chip CH when the flip chip CH is not flipped over. The flip chip CH may include a plurality of internal solder balls 22 which are spaced apart from one another to be electrically connected with the internal wiring pads 18. The internal solder balls 22 may be replaced with internal bumps.

The internal solder balls 22 (or the internal bumps) may include at least one metal or a metal alloy of copper (Cu), aluminum (Al), nickel (Ni), silver (Ag), gold (Au), platinum (Pt), zinc (Sn), lead (Pb), titanium (Ti), chromium (Cr), palladium (Pd), indium (In), zinc (Zn), and/or carbon (C).

The internal solder balls 22 may be connected with chip bumps 32 which are formed under the flip chip CH. The chip bumps 32 may be insulated from one another by a passivation layer 34. The chip bumps 32 may be configured as a metal layer. The chip bumps 32 may include Ti, Cu, or titanium tungsten (TiW).

The flip chip CH may include an individual device. The individual device may include various microelectronics devices (for example, a metal-oxide-semiconductor field effect transistor (MOSFET) such as a complementary metal-insulator-semiconductor (CMOS) transistor, system large scale integration (LSI), an image sensor such as a CMOS imaging sensor (CIS), a micro-electro-mechanical system (MEMS), an active device, and/or a passive device).

In some embodiments, the flip chip CH may include a logic chip, a power management integrated circuit (PMIC) chip, or a memory chip. In some embodiments, the logic chip may include a memory controller chip, a central processing unit (CPU) chip, a graphics processing unit (GPU) chip, or an application processor (AP) chip.

In some embodiments, the memory chip may include a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

The molding layer 36 may bury the core trench group 26-1 and may seal the flip chip CH, on the wiring substrate WS-1. The molding layer 36 may bury the core trench group 26-1, on the wiring substrate WS-1. For example, the molding layer 36 may extend into the core trench group 26-1. For example, the molding layer 36 may extend into the core trenches 26a to 26c. The molding layer 36 may seal a region between the internal wiring pads 18, a region between the internal solder balls 22, and the flip chip CH without a void. For example, the molding layer 36 may extend into a region between respective ones of the internal wiring pads 18 and a region between respective ones of the internal solder balls 22 without leaving a void therebetween. The molding layer 36 may be buried between the chip bumps 32 and between the internal solder balls 22 without a void. For example, the molding layer 36 may extend between respective ones of the chip bumps 32 and between respective ones of the internal solder balls 22 without leaving a void therebetween. The molding layer 36 may be formed on both side surfaces and an upper surface of the chip body 30 to seal the flip chip CH. For example, the molding layer 36 may be on the flip chip CH.

The molding layer 36 may include, for example, a silicon-based material, a thermo-curable material, a thermo-plastic material, or an ultraviolet (UV) treatment material. The molding layer 36 may include a polymer such as resin, and for example, may include an epoxy molding compound (EMC).

A plurality of external wiring pads 20 may be spaced apart from one another under the wiring substrate WS-1 (e.g., on a lower surface of the wiring substrate WS-1) and may be insulated from one another by the lower protection layer 14. The plurality of external solder balls 24 may be formed in the external wiring pads 20. The external wiring pads 20 may include the same material as that of the internal wiring pads 18. The external solder balls 24 may include the same material as that of the internal solder balls 22.

The flip chip semiconductor package PK1 configured as described above may include the core trench group 26-1 including the plurality of core trenches 26a to 26c at a certain portion (for example, a center portion) of the wiring substrate WS-1. Therefore, in the flip chip semiconductor package PK1, the molding layer 36 may be easily filled between the internal solder balls 22 or between the chip bumps 32, and a contact area between the molding layer 36 and the wiring substrate WS-1 may increase, thereby enhancing package reliability.

In the flip chip semiconductor package PK1, because the molding layer 36 is not formed under the wiring substrate WS-1 (e.g., is not on a lower surface of the wiring substrate WS-1), an area where the external solder balls 24 are arranged may increase. In other words, in the flip chip semiconductor package PK1, the degree of freedom of the external solder balls 24 under the wiring substrate WS-1 may increase.

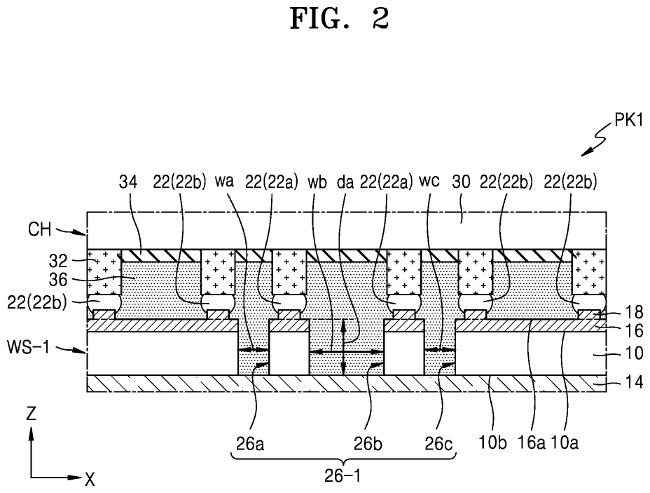

FIG. 2 is a partially enlarged view of the flip chip semiconductor package PK1 of FIG. 1.

In detail, FIG. 2 illustrates the flip chip CH disposed in the opening region 44 of the wiring substrate WS-1 of FIG. 1. In FIG. 2, descriptions which are the same as or similar to the descriptions of FIG. 1 will be briefly given or are omitted. The core trench group 26-1 including the core trenches 26a to 26c may be formed between an upper surface 10a and a lower surface 10b of the core layer 10 or between an upper surface 16a of the wiring layer 16 and a lower surface 10b of the core layer 10, in the wiring substrate WS-1. The core trenches 26a to 26c may pass or extend through a region between the upper surface 10a and the lower surface 10b of the core layer 10 or a region between the upper surface 16a of the wiring layer 16 and the lower surface 10b of the core layer 10.

The core trench group 26-1 may include the core trenches 26a to 26c which are spaced apart from one another in a first direction (an X direction). The core trenches 26a to 26c may include a first core trench 26a, a second core trench 26b, and a third core trench 26c. Widths wa to wc of the core trenches 26a to 26c may differ or may be equal to one another, or may be a combination thereof.

In some embodiments, the first core trench 26a, the second core trench 26b, and the third core trench 26c may respectively have a first width wa, a second width wb, and a third width wc. Each of the first core trench 26a, the second core trench 26b, and the third core trench 26c may have a depth da. The first width wa may be the same as the third width wc. The second width wb may be greater than the first width wa and the third width wc. Each of the first width wa, the second width wb, and the third width wc may be several mm. The depth da may be several mm.

The flip chip CH may include the internal solder balls 22 connected to the internal wiring pads 18. The internal solder balls 22 may be replaced with internal bumps. In some embodiments, the internal solder balls 22 may include a plurality of signal internal solder balls 22a formed at a center portion of the wiring substrate WS-1 and a plurality of chip supporting internal solder balls 22b formed at a peripheral portion of the wiring substrate WS-1. For example, the plurality of signal internal solder balls 22a may be electrically connected to the chip bumps 32 and/or the internal wiring pads 18. The plurality of signal internal solder balls 22a may, for example, be respectively formed between adjacent ones of the first to third core trenches 26a to 26c. For example, the plurality of chip supporting internal solder balls 22b may serve as dummy internal solder balls. In some embodiments, the plurality of chip supporting internal solder balls 22b may not be electrically connected to the to the chip bumps 32 and/or the internal wiring pads 18. The plurality of chip supporting internal solder balls 22b may be formed, for example, to provide stability and support for the flip chip CH and/or flip chip semiconductor package PKL. The flip chip CH may include the internal solder balls 22 having various shapes. The molding layer 36 may be formed between the first to third core trenches 26a to 26c and between the internal wiring pads 18. For example, the molding layer 36 may extend into the first to third core trenches 26a to 26c and may extend between respective ones of the internal wiring pads 18.

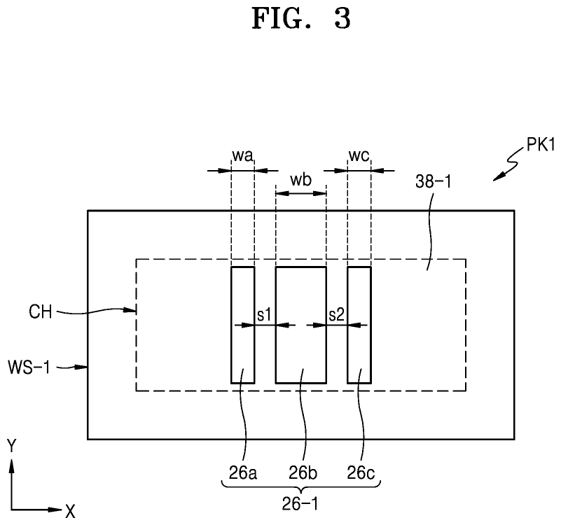

FIG. 3 is a layout view of the flip chip semiconductor package PK1 of FIGS. 1 and 2.

In detail, FIG. 3 illustrates a plan view of the flip chip semiconductor package PK1 in a direction (an X direction) and a second direction (a Y direction) with respect to a surface of the wiring substrate WS-1. In FIG. 3, descriptions which are the same as or similar to the descriptions of FIGS. 1 and 2 will be briefly given or are omitted. In the flip chip semiconductor package PK1, the flip chip CH may be disposed on the wiring substrate WS-1.

The core trench group 26-1 including the first to third core trenches 26a to 26c may be disposed in the wiring substrate WS-1. The core trench group 26-1 may be disposed at a center portion of the wiring substrate WS-1 one-dimensionally. A pad formation region 38-1 with internal wiring pads formed therein may be disposed at a portion, except the core trench group 26-1, of the wiring substrate WS-1. A region between the first to third core trenches 26a to 26c and an outer region of each of the first to third core trenches 26a to 26c may each be the pad formation region 38-1.

The first to third core trenches 26a to 26c may be one-dimensionally arranged to extend from a front surface of the flip chip CH to a rear surface of the flip chip CH. For example, the first to third core trenches 26a to 26c may extend in the second direction (the Y direction) from a first region adjacent to a front surface of the flip chip CH to a second region adjacent to a rear surface of the flip chip CH. The rear surface, for example, may be a surface of the flip chip CH opposite to the front surface. The second core trench 26b may be spaced apart from the first core trench 26a in the first direction (the X direction). The second core trench 26b may be spaced apart from the first core trench 26a by a first separation distance s1.

The third core trench 26c may be spaced apart from the second core trench 26b in the first direction (the X direction). The third core trench 26c may be spaced apart from the second core trench 26b by a second separation distance s2.

The first and second separation distances s1 and s2 between the first to third core trenches 26a to 26c may differ or be equal to each other. In some embodiments, the first and second separation distances s1 and s2 may be equal to each other. In some embodiments, each of the first and second separation distances s1 and s2 may be several mm.

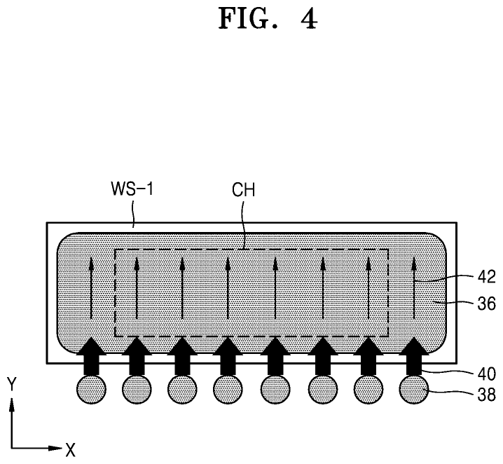

FIG. 4 is a plan view for describing a method of forming a molding layer of the flip chip semiconductor package PK1 of FIGS. 1 to 3.

In detail, in FIG. 3, descriptions which are the same as or similar to the descriptions of FIGS. 1 to 3 will be briefly given or are omitted. In FIG. 4, a first direction (an X direction) and a second direction (a Y direction) may each be a direction parallel to a surface of a wiring substrate WS-1. The second direction (the Y direction) may be a direction perpendicular to the first direction (the X direction).

A flip chip CH may be disposed on the wiring substrate WS-1. A molding layer 36 may be formed on the wiring substrate WS-1 and the flip chip CH. In order to form the molding layer 36, a plurality of molding sources 38 may be arranged at one side of the wiring substrate WS-1.

The molding sources 38 may be spaced apart from one another in the first direction (the X direction). A molding material discharged from the molding sources 38 may move in the second direction (the Y direction) to form the molding layer 36 as illustrated by a first arrow 40 and a second arrow 42.

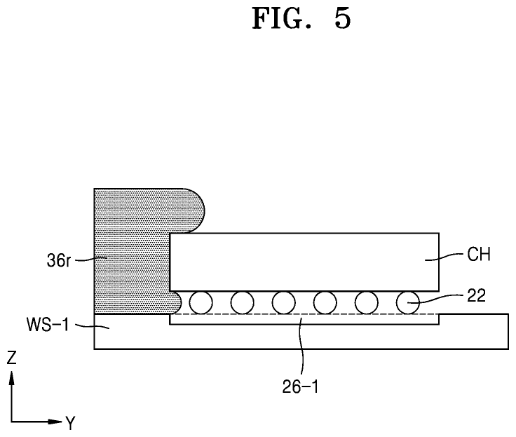

FIGS. 5 to 7 are cross-sectional views for describing a method of forming the molding layer of the flip chip semiconductor package PK1 of FIGS. 1 to 3.

In detail, in FIGS. 5 to 7, descriptions which are the same as or similar to the descriptions of FIGS. 1 to 4 will be briefly given or are omitted. In FIGS. 5 to 7, a second direction (a Y direction) may be a direction parallel to a surface of a wiring substrate WS-1. The second direction (the Y direction) may be a direction perpendicular to a first direction (an X direction) in the surface of the wiring substrate WS-1. A third direction (a Z direction) may be a direction vertical to the surface of the wiring substrate WS-1.

Referring to FIG. 5, a flip chip CH may be disposed on the wiring substrate WS-1. A core trench group 26-1 may be formed at a center portion of the wiring substrate WS-1. The core trench group 26-1 may include one of first to third core trenches (26a to 26c of FIGS. 1 to 3).

A plurality of internal solder balls 22 may be disposed under the flip chip CH. The internal solder balls 22 may be replaced with internal bumps. The internal solder balls 22 may be spaced apart from one another in the second direction (the Y direction). The internal solder balls 22 may be disposed on the core trench group 26-1. A molding material 36r may be injected from one side of the wiring substrate WS-1 into the other side of the wiring substrate WS-1. In other words, the molding material 36r injected from molding sources (38 of FIG. 4) may be injected from the one side of the wiring substrate WS-1 in the second direction (the Y direction). FIG. 5 illustrates an example where the molding material 36r is formed at only the one side of the wiring substrate WS-1.

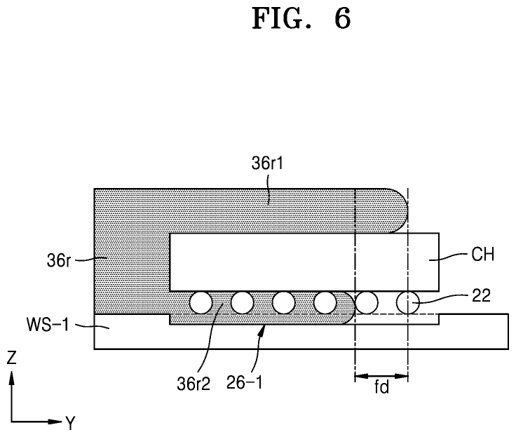

Referring to FIG. 6, the molding material 36r may be injected from the one side of the wiring substrate WS-1 into the other side of the wiring substrate WS-1. Accordingly, the molding material 36r may be filled into a portion of the core trench group 26-1 and may be formed on the flip chip CH. As illustrated in FIG. 6, an outermost distance difference (e.g., fd) between a molding material 36r1 flowing on the wiring substrate WS-1 and a molding material 36r2 flowing under the wiring substrate WS-1 may occur due to a flow speed difference therebetween.

The flow speed difference between the molding material 36r1 on the wiring substrate WS-1 and the molding material 36r2 under the wiring substrate WS-1 may be caused by the internal solder balls 22 and the core trench group 26-1. In other words, the molding material 36r2 under the wiring substrate WS-1 may be less in flow speed than the molding material 36r1 on the wiring substrate WS-1 due to the internal solder balls 22 and the core trench group 26-1. FIG. 6 illustrates an example where the molding material 36r is formed at only a portion of a center portion of the wiring substrate WS-1.

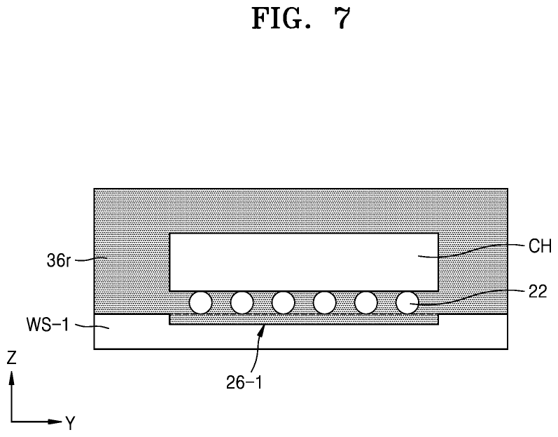

Referring to FIG. 7, a molding material (36r of FIG. 6) may be continuously injected from the one side of the wiring substrate WS-1 into the other side of the wiring substrate WS-1, and thus, the molding layer 36 may be formed. The molding layer 36 may bury the core trench group 26-1 and may seal the flip chip CH, on the wiring substrate WS-1. The molding layer 36 may bury the core trench group 26-1 on the wiring substrate WS-1 and may seal a region between the internal solder balls 22 and both side surfaces and an upper surface of the flip chip CH. For example, the molding layer 36 may extend into the core trench group 26-1. For example, the molding layer 36 may be on the flip chip CH.

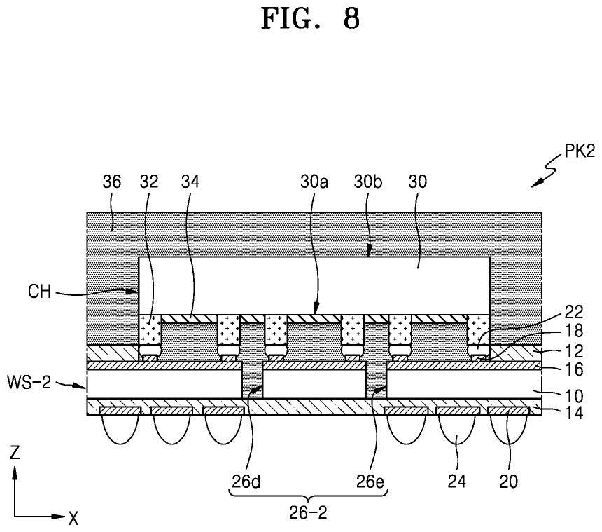

FIG. 8 is a cross-sectional view for describing a flip chip semiconductor package PK2 according to some embodiments.

In detail, except for that a core trench group 26-2 is formed in a wiring substrate WS-2, the flip chip semiconductor package PK2 may be the same as the flip chip semiconductor package PK1 of FIGS. 1 and 2. In FIG. 8, descriptions which are the same as or similar to the descriptions of FIGS. 1 and 2 will be briefly given or are omitted.

The flip chip semiconductor package PK2 may include a wiring substrate WS-2, a core trench group 26-2, a flip chip CH, and a molding layer 36. FIG. 8 is a cross-sectional view taken in a first direction (an X direction) and a third direction (a Z direction) with respect to a surface of the wiring substrate WS-2. The third direction may be a direction vertical to the surface of the wiring substrate WS-2.

The wiring substrate WS-2 may include a core layer 10 and a lower protection layer 14 which is formed on a lower surface of the core layer 10. The wiring substrate WS-2 may include a wiring layer 16, an upper protection layer 12 (e.g., an upper passivation layer), and internal wiring pads 18.

A core trench group 26-2 may include a plurality of core trenches 26d and 26e which are spaced apart from one another on the lower protection layer 14. The core trench group 26-2 may be formed in the wiring layer 16 and the core layer 10, on the lower protection layer 14. The core trenches 26d and 26e may be spaced apart from one another at a center portion of the wiring substrate WS-2. The core trench group 26-2 may include first and second core trenches 26d and 26e.

The flip chip CH may be disposed on the wiring substrate WS-2 and the core trench group 26-2. The flip chip CH may be disposed on the wiring layer 16, the upper protection layer 12, and the core trench group 26-2.

The flip chip CH may include a chip body 30. The chip body 30 may include a first surface 30a and a second surface 30b. The internal solder balls 22 may be connected with chip bumps 32 which are formed under the flip chip CH. The internal solder balls 22 may be replaced with internal bumps. The chip bumps 32 may be insulated from one another by a passivation layer 34.

The molding layer 36 may bury the core trench group 26-2 and may seal the flip chip CH, on the wiring substrate WS-2. For example, the molding layer 36 may extend into the core trench group 26-2. For example, the molding layer 36 may extend into the core trenches 26d and 26e.

The molding layer 36 may bury the core trench group 26-2 on the wiring substrate WS-2 and may seal a region between the internal wiring pads 18, a region between the internal solder balls 22, and the flip chip CH. The molding layer 36 may be formed on both side surfaces and an upper surface of the chip body 30 to seal the flip chip CH. For example, the molding layer 36 may be on the flip chip CH.

A plurality of external wiring pads 20 may be spaced apart from one another under the wiring substrate WS-2 and may be insulated from one another by the lower protection layer 14. The plurality of external solder balls 24 may be formed in the external wiring pads 20.

The flip chip semiconductor package PK2 may include the core trench group 26-2 including the plurality of core trenches 26d and 26e at a certain portion (for example, a center portion) of the wiring substrate WS-2. Therefore, in the flip chip semiconductor package PK2, the molding layer 36 may be easily filled between the internal solder balls 22 or between the chip bumps 32, and a contact area between the molding layer 36 and the wiring substrate WS-2 may increase, thereby enhancing package reliability.

In the flip chip semiconductor package PK2, because the molding layer 36 is not formed under the wiring substrate WS-2 (e.g., is not on a lower surface of the wiring substrate WS-2), an area where the external solder balls 24 are arranged may increase, and the degree of freedom of the external solder balls 24 may increase.

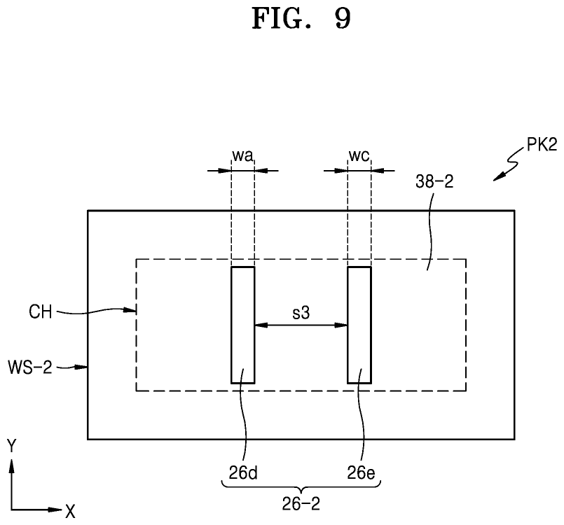

FIG. 9 is a layout view of the flip chip semiconductor package PK2 of FIG. 8.

In detail, FIG. 9 illustrates a plan view of the flip chip semiconductor package PK2 in a direction (an X direction) and a second direction (a Y direction) with respect to a surface of the wiring substrate WS-2. In FIG. 9, descriptions which are the same as or similar to the descriptions of FIG. 8 will be briefly given or are omitted. In the flip chip semiconductor package PK2, the flip chip CH may be disposed on the wiring substrate WS-2.

The core trench group 26-2 including the first and second core trenches 26d and 26e may be disposed in the wiring substrate WS-2. The core trench group 26-2 may be disposed at a center portion of the wiring substrate WS-2 one-dimensionally. A pad formation region 38-2 with internal wiring pads formed therein may be disposed at a portion, except the core trench group 26-2, of the wiring substrate WS-2. A region between the first and second core trenches 26d and 26e and an outer region of each of the first and second core trenches 26d and 26e may each be the pad formation region 38-2.

The first and second core trenches 26d and 26e may be one-dimensionally arranged to extend from a front surface of the flip chip CH to a rear surface of the flip chip CH. For example, the first and second core trenches 26d and 26e may extend in the second direction (the Y direction) from a first region adjacent to a front surface of the flip chip CH to a second region adjacent to a rear surface of the flip chip CH. The rear surface, for example, may be a surface of the flip chip CH opposite to the front surface. The second core trench 26e may be spaced apart from the first core trench 26d in the first direction (the X direction). In some embodiments, the second core trench 26e may be spaced apart from the first core trench 26d by a third separation distance s3. In some embodiments, the third separation distance s3 may be several mm.

In some embodiments, the first core trench 26d and the second core trench 26e may respectively have a first width wa and a third width wc. The first width wa and the third width wc may differ, but in other embodiments, the first width wa and the third width wc may be equal to one another. Each of the first width wa and the third width wc may be several mm.

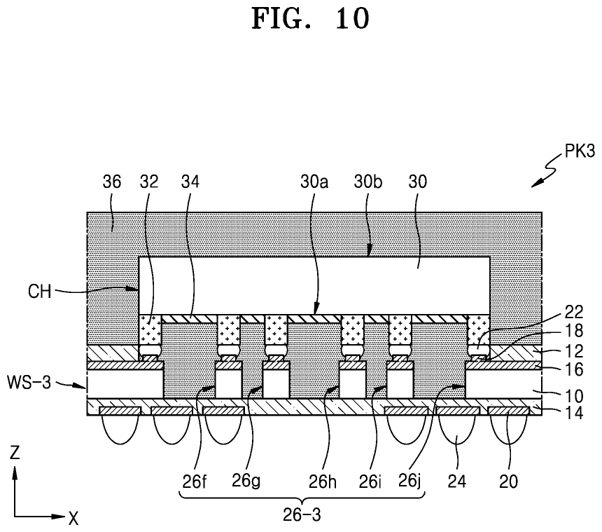

FIG. 10 is a cross-sectional view for describing a flip chip semiconductor package PK3 according to some embodiments.

In detail, except for that a core trench group 26-3 is formed in a wiring substrate WS-3, the flip chip semiconductor package PK3 may be the same as the flip chip semiconductor package PK1 of FIGS. 1 and 2. In FIG. 10, descriptions which are the same as or similar to the descriptions of FIGS. 1 and 2 will be briefly given or are omitted.

The flip chip semiconductor package PK3 may include a wiring substrate WS-3, a core trench group 26-3, a flip chip CH, and a molding layer 36. FIG. 10 may be a cross-sectional view taken in a first direction (an X direction) and a third direction (a Z direction) with respect to a surface of the wiring substrate WS-3. The third direction may be a direction vertical to the surface of the wiring substrate WS-3.

The wiring substrate WS-3 may include a core layer 10 and a lower protection layer 14 which is formed on a lower surface of the core layer 10. The wiring substrate WS-3 may include a wiring layer 16, an upper protection layer 12 (e.g., an upper passivation layer), and internal wiring pads 18.

A core trench group 26-3 may include a plurality of core trenches 26f to 26j which are spaced apart from one another on the lower protection layer 14. The core trench group 26-3 may be formed in the wiring layer 16 and the core layer 10, on the lower protection layer 14. The core trenches 26f to 26j may be spaced apart from one another at a center portion of the wiring substrate WS-3. The core trench group 26-3 may include first to fifth core trenches 26f to 26j.

The flip chip CH may be disposed on the wiring substrate WS-3 and the core trench group 26-3. The flip chip CH may be disposed on the wiring layer 16, the upper protection layer 12, and the core trench group 26-3.

The flip chip CH may include a chip body 30. The chip body 30 may include a first surface 30a and a second surface 30b. The internal solder balls 22 may be connected with chip bumps 32 which are formed under the flip chip CH. The internal solder balls 22 may be replaced with internal bumps. The chip bumps 32 may be insulated from one another by a passivation layer 34.

The molding layer 36 may bury the core trench group 26-3 and may seal the flip chip CH, on the wiring substrate WS-3. For example, the molding layer 36 may extend into the core trench group 26-3. For example, the molding layer 36 may extend into the core trenches 26f to 26j. The molding layer 36 may bury the core trench group 26-3 on the wiring substrate WS-3 and may seal a region between the internal wiring pads 18, a region between the internal solder balls 22, and the flip chip CH. The molding layer 36 may be formed on both side surfaces and an upper surface of the chip body 30 to seal the flip chip CH. For example, the molding layer 36 may be on the flip chip CH.

A plurality of external wiring pads 20 may be spaced apart from one another under the wiring substrate WS-3 and may be insulated from one another by the lower protection layer 14. The plurality of external solder balls 24 may be formed in the external wiring pads 20.

The flip chip semiconductor package PK3 may include the core trench group 26-3 including the plurality of core trenches 26f to 26j at a certain portion (for example, a center portion) of the wiring substrate WS-3. Therefore, in the flip chip semiconductor package PK3, the molding layer 36 may be easily filled between the internal solder balls 22 or between the chip bumps 32, and a contact area between the molding layer 36 and the wiring substrate WS-3 may increase, thereby enhancing package reliability.

In the flip chip semiconductor package PK3, because the molding layer 36 is not formed under the wiring substrate WS-3 (e.g., is not on a lower surface of the wiring substrate WS-3), an area where the external solder balls 24 are arranged may increase, and the degree of freedom of the external solder balls 24 may increase.

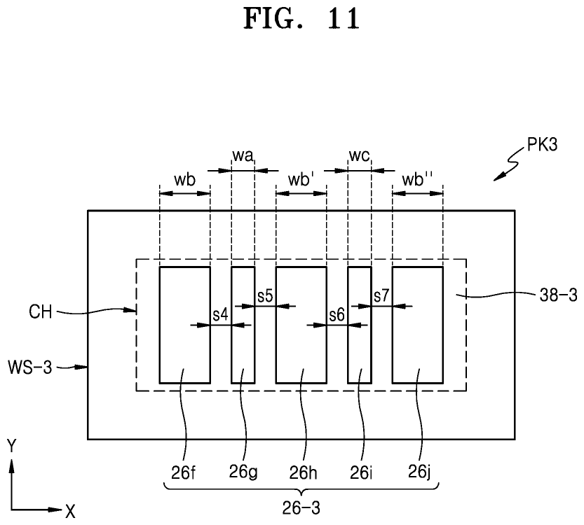

FIG. 11 is a layout view of the flip chip semiconductor package PK3 of FIG. 10.

In detail, FIG. 11 illustrates a plan view of the flip chip semiconductor package PK3 in a direction (an X direction) and a second direction (a Y direction) with respect to a surface of the wiring substrate WS-3. In FIG. 11, descriptions which are the same as or similar to the descriptions of FIG. 10 will be briefly given or are omitted. In the flip chip semiconductor package PK3, the flip chip CH may be disposed on the wiring substrate WS-3.

The core trench group 26-3 including the first to fifth core trenches 26f to 26j may be disposed in the wiring substrate WS-3. The core trench group 26-3 may be disposed at a center portion of the wiring substrate WS-3 one-dimensionally. A pad formation region 38-3 with internal wiring pads formed therein may be disposed at a portion, except the core trench group 26-3, of the wiring substrate WS-3. A region between the first to fifth core trenches 26f to 26j and an outer region of each of the first to fifth core trenches 26f to 26j may each be the pad formation region 38-3.

The first to fifth core trenches 26f to 26j may be one-dimensionally arranged to extend from a front surface of the flip chip CH to a rear surface of the flip chip CH. For example, the first to fifth core trenches 26f to 26j may extend in the second direction (the Y direction) from a first region adjacent to a front surface of the flip chip CH to a second region adjacent to a rear surface of the flip chip CH. The rear surface, for example, may be a surface of the flip chip CH opposite to the front surface. The second core trench 26g may be spaced apart from the first core trench 26f in the first direction (the X direction). The second core trench 26g may be spaced apart from the first core trench 26f by a fourth separation distance s4.

The third core trench 26h may be spaced apart from the second core trench 26g in the first direction (the X direction). The third core trench 26h may be spaced apart from the second core trench 26g by a fifth separation distance s5.

The fourth core trench 26i may be spaced apart from the third core trench 26h in the first direction (the X direction). The fourth core trench 26i may be spaced apart from the third core trench 26h by a sixth separation distance s6.

The fifth core trench 26j may be spaced apart from the fourth core trench 26i in the first direction (the X direction). The fifth core trench 26j may be spaced apart from the fourth core trench 26i by a seventh separation distance s7.

The fourth to seventh separation distances s4 to s7 of the first to fifth core trenches 26f to 26j may differ or may be equal to one another, or may be a combination thereof. In some embodiments, the fourth to seventh separation distances s4 to s7 may be equal to one another. Each of the fourth to seventh separation distances s4 to s7 may be several mm.

The first core trench 26f, the third core trench 26h, and the fifth core trench 26j may have second widths wb, wb′, and wb″. The second core trench 26g and the fourth core trench 26i may respectively have a first width wa and a third width wc. Widths wb, wa, wb′, wc, and wb″ of the first to fifth core trenches 26f to 26j may differ or may be equal to one another, or may be a combination thereof. In some embodiments, the first width wa may be the same as the third width wc. The second widths wb, wb′, and wb″ may be greater than the first width wa and the third width wc. Each of the first width wa, the second widths wb, wb′, and wb″, and the third width wc may be several mm.

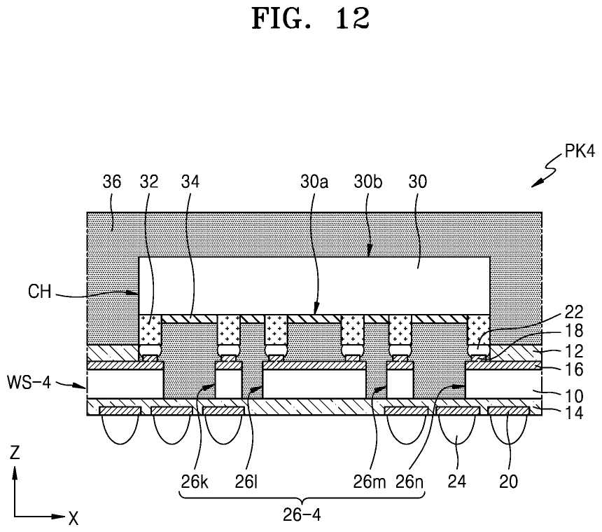

FIG. 12 is a cross-sectional view for describing a flip chip semiconductor package PK4 according to some embodiments.

In detail, except for that a core trench group 26-4 is formed in a wiring substrate WS-4, the flip chip semiconductor package PK4 may be the same as the flip chip semiconductor package PK1 of FIGS. 1 and 2. In FIG. 12, descriptions which are the same as or similar to the descriptions of FIGS. 1 and 2 will be briefly given or are omitted.

The flip chip semiconductor package PK4 may include a wiring substrate WS-4, a core trench group 26-4, a flip chip CH, and a molding layer 36. FIG. 12 may be a cross-sectional view taken in a first direction (an X direction) and a third direction (a Z direction) with respect to a surface of the wiring substrate WS-4. The third direction may be a direction vertical to the surface of the wiring substrate WS-4.

The wiring substrate WS-4 may include a core layer 10 and a lower protection layer 14 which is formed on a lower surface of the core layer 10. The wiring substrate WS-4 may include a wiring layer 16, an upper protection layer 12 (e.g., an upper passivation layer), and internal wiring pads 18.

A core trench group 26-4 may include a plurality of core trenches 26k to 26n which are spaced apart from one another on the lower protection layer 14. The core trench group 26-4 may be formed in the wiring layer 16 and the core layer 10, on the lower protection layer 14. The core trenches 26k to 26n may be spaced apart from one another at a center portion of the wiring substrate WS-4. The core trench group 26-4 may include first to fourth core trenches 26k to 26n.

The flip chip CH may be disposed on the wiring substrate WS-4 and the core trench group 26-4. The flip chip CH may be disposed on the wiring layer 16, the upper protection layer 12, and the core trench group 26-4.

The flip chip CH may include a chip body 30. The chip body 30 may include a first surface 30a and a second surface 30b. The internal solder balls 22 may be connected with chip bumps 32 which are formed under the flip chip CH. The internal solder balls 22 may be replaced with internal bumps. The chip bumps 32 may be insulated from one another by a passivation layer 34.

The molding layer 36 may bury the core trench group 26-4 and may seal the flip chip CH, on the wiring substrate WS-4. For example, the molding layer 36 may extend into the core trench group 26-4. For example, the molding layer 36 may extend into the core trenches 26k to 26n. The molding layer 36 may bury the core trench group 26-4 on the wiring substrate WS-4 and may seal a region between the internal wiring pads 18, a region between the internal solder balls 22, and the flip chip CH. The molding layer 36 may be formed on both side surfaces and an upper surface of the chip body 30 to seal the flip chip CH. For example, the molding layer 36 may be on the flip chip CH.

A plurality of external wiring pads 20 may be spaced apart from one another under the wiring substrate WS-4 and may be insulated from one another by the lower protection layer 14. The plurality of external solder balls 24 may be formed in the external wiring pads 20.

The flip chip semiconductor package PK4 may include the core trench group 26-4 including the plurality of core trenches 26k to 26n at a certain portion (for example, a center portion) of the wiring substrate WS-4. Therefore, in the flip chip semiconductor package PK4, the molding layer 36 may be easily filled between the internal solder balls 22 or between the chip bumps 32, and a contact area between the molding layer 36 and the wiring substrate WS-4 may increase, thereby enhancing package reliability.

In the flip chip semiconductor package PK4, because the molding layer 36 is not formed under the wiring substrate WS-4 (e.g., is not on a lower surface of the wiring substrate WS-4), an area where the external solder balls 24 are arranged may increase, and the degree of freedom of the external solder balls 24 may increase.

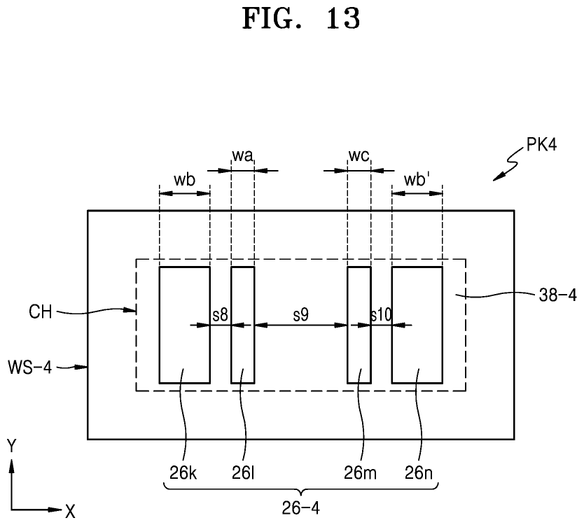

FIG. 13 is a layout view of the flip chip semiconductor package PK4 of FIG. 12.

In detail, FIG. 13 illustrates a plan view of the flip chip semiconductor package PK4 in a direction (an X direction) and a second direction (a Y direction) with respect to a surface of the wiring substrate WS-4. In FIG. 13, descriptions which are the same as or similar to the descriptions of FIG. 12 will be briefly given or are omitted. In the flip chip semiconductor package PK4, the flip chip CH may be disposed on the wiring substrate WS-4.

The core trench group 26-4 including the first to fourth core trenches 26k to 26n may be disposed in the wiring substrate WS-4. The core trench group 26-4 may be disposed at a center portion of the wiring substrate WS-4 one-dimensionally. A pad formation region 38-4 with internal wiring pads formed therein may be disposed at a portion, except the core trench group 26-4, of the wiring substrate WS-4. A region between the first to fourth core trenches 26k to 26n and an outer region of each of the first to fourth core trenches 26k to 26n may each be the pad formation region 38-4.

The first to fourth core trenches 26k to 26n may be one-dimensionally arranged to extend from a front surface of the flip chip CH to a rear surface of the flip chip CH. For example, the first to fourth core trenches 26k to 26n may extend in the second direction (the Y direction) from a first region adjacent to a front surface of the flip chip CH to a second region adjacent to a rear surface of the flip chip CH. The rear surface, for example, may be a surface of the flip chip CH opposite to the front surface. The second core trench 26l may be spaced apart from the first core trench 26k in the first direction (the X direction). The second core trench 26l may be spaced apart from the first core trench 26k by an eighth separation distance s8.

The third core trench 26m may be spaced apart from the second core trench 26l in the first direction (the X direction). The third core trench 26m may be spaced apart from the second core trench 26l by a ninth separation distance s9.

The fourth core trench 26n may be spaced apart from the third core trench 26m in the first direction (the X direction). The fourth core trench 26n may be spaced apart from the third core trench 26m by a tenth separation distance s10.

The eighth to tenth separation distances s8 to s10 of the first to fourth core trenches 26k to 26n may differ or may be equal to one another, or may be a combination thereof. In some embodiments, the eighth and tenth separation distances s8 and s10 may be equal to each other. The ninth separation distance s9 may be greater than the eighth and tenth separation distances s8 and s10. Each of the eighth to tenth separation distances s8 to s10 may be several mm.

The first core trench 26k and the fourth core trench 26n may have second widths wb and wb′. The second core trench 26l and the third core trench 26m may respectively have a first width wa and a third width wc. Widths wb, wa, wc, and wb′ of the first to fourth core trenches 26k to 26n may differ or may be equal to one another, or may be a combination thereof. In some embodiments, the first width wa may be the same as the third width wc. The second widths wb and wb′ may be greater than the first width wa and the third width wc. Each of the first width wa, the second widths wb and wb′, and the third width wc may be several mm.

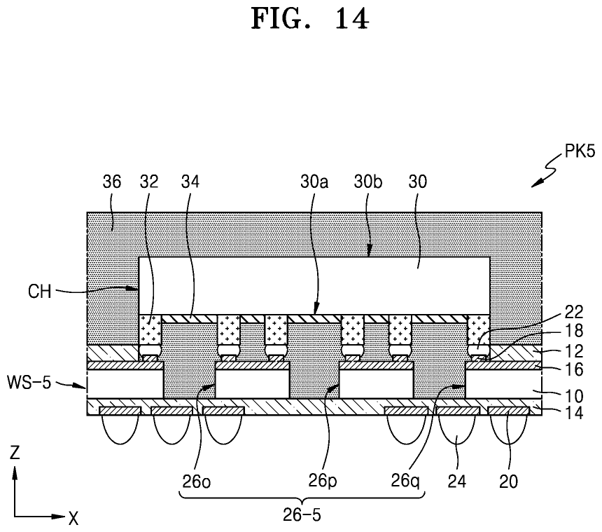

FIG. 14 is a cross-sectional view for describing a flip chip semiconductor package PK5 according to some embodiments.

In detail, except for that a core trench group 26-5 is formed in a wiring substrate WS-5, the flip chip semiconductor package PK5 may be the same as the flip chip semiconductor package PK1 of FIGS. 1 and 2. In FIG. 14, descriptions which are the same as or similar to the descriptions of FIGS. 1 and 2 will be briefly given or are omitted.

The flip chip semiconductor package PK5 may include a wiring substrate WS-5, a core trench group 26-5, a flip chip CH, and a molding layer 36. FIG. 14 is a cross-sectional view taken in a first direction (an X direction) and a third direction (a Z direction) with respect to a surface of the wiring substrate WS-5. The third direction may be a direction vertical to the surface of the wiring substrate WS-5.

The wiring substrate WS-5 may include a core layer 10 and a lower protection layer 14 which is formed on a lower surface of the core layer 10. The wiring substrate WS-5 may include a wiring layer 16, an upper protection layer 12 (e.g., an upper passivation layer), and internal wiring pads 18.

A core trench group 26-5 may include a plurality of core trenches 26o to 26q which are spaced apart from one another on the lower protection layer 14. The core trench group 26-5 may be formed in the wiring layer 16 and the core layer 10, on the lower protection layer 14. The core trenches 26o to 26q may be spaced apart from one another at a center portion of the wiring substrate WS-5. The core trench group 26-5 may include first to third core trenches 26o to 26q.

The flip chip CH may be disposed on the wiring substrate WS-5 and the core trench group 26-5. The flip chip CH may be disposed on the wiring layer 16, the upper protection layer 12, and the core trench group 26-5.

The flip chip CH may include a chip body 30. The chip body 30 may include a first surface 30a and a second surface 30b. The internal solder balls 22 may be connected with chip bumps 32 which are formed under the flip chip CH. The internal solder balls 22 may be replaced with internal bumps. The chip bumps 32 may be insulated from one another by a passivation layer 34.

The molding layer 36 may bury the core trench group 26-5 and may seal the flip chip CH, on the wiring substrate WS-5. For example, the molding layer 36 may extend into the core trench group 26-5. For example, the molding layer 36 may extend into the core trenches 26o to 26q. The molding layer 36 may bury the core trench group 26-5 on the wiring substrate WS-5 and may seal a region between the internal wiring pads 18, a region between the internal solder balls 22, and the flip chip CH. The molding layer 36 may be formed on both side surfaces and an upper surface of the chip body 30 to seal the flip chip CH. For example, the molding layer 36 may be on the flip chip CH.

A plurality of external wiring pads 20 may be spaced apart from one another under the wiring substrate WS-5 and may be insulated from one another by the lower protection layer 14. The plurality of external solder balls 24 may be formed in the external wiring pads 20.

The flip chip semiconductor package PK5 may include the core trench group 26-5 including the plurality of core trenches 26o to 26q at a certain portion (for example, a center portion) of the wiring substrate WS-5. Therefore, in the flip chip semiconductor package PK5, the molding layer 36 may be easily filled between the internal solder balls 22 or between the chip bumps 32, and a contact area between the molding layer 36 and the wiring substrate WS-5 may increase, thereby enhancing package reliability.

In the flip chip semiconductor package PK5, because the molding layer 36 is not formed under the wiring substrate WS-5 (e.g., is not on a lower surface of the wiring substrate WS-5), an area where the external solder balls 24 are arranged may increase, and the degree of freedom of the external solder balls 24 may increase.

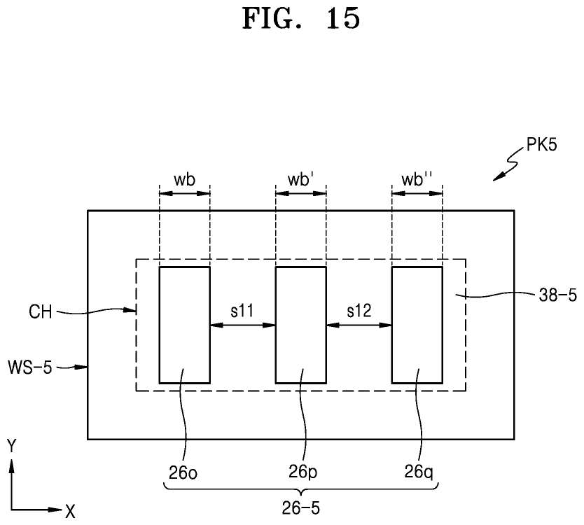

FIG. 15 is a layout view of the flip chip semiconductor package PK5 of FIG. 14.

In detail, FIG. 15 illustrates a plan view of the flip chip semiconductor package PK5 in a direction (an X direction) and a second direction (a Y direction) with respect to a surface of the wiring substrate WS-5. In FIG. 15, descriptions which are the same as or similar to the descriptions of FIG. 14 will be briefly given or are omitted. In the flip chip semiconductor package PK5, the flip chip CH may be disposed on the wiring substrate WS-5.

The core trench group 26-5 including the first to third core trenches 26o to 26q may be disposed in the wiring substrate WS-5. The core trench group 26-5 may be disposed at a center portion of the wiring substrate WS-5 one-dimensionally. A pad formation region 38-5 with internal wiring pads formed therein may be disposed at a portion, except the core trench group 26-5, of the wiring substrate WS-5. A region between the first to third core trenches 26o to 26q and an outer region of each of the first to third core trenches 26o to 26q may each be the pad formation region 38-5.

The first to third core trenches 26o to 26q may be one-dimensionally arranged to extend from a front surface of the flip chip CH to a rear surface of the flip chip CH. For example, the first to third core trenches 26o to 26q may extend in the second direction (the Y direction) from a first region adjacent to a front surface of the flip chip CH to a second region adjacent to a rear surface of the flip chip CH. The rear surface, for example, may be a surface of the flip chip CH opposite to the front surface. The second core trench 26p may be spaced apart from the first core trench 26o in the first direction (the X direction). The second core trench 26p may be spaced apart from the first core trench 26o by an eleventh separation distance s11.

The third core trench 26q may be spaced apart from the second core trench 26p in the first direction (the X direction). The third core trench 26q may be spaced apart from the second core trench 26p by a twelfth separation distance s12. The eleventh and twelfth separation distances s11 and s12 may differ, but in other embodiments, the eleventh and twelfth separation distances s11 and s12 may be equal to each other. Each of the eleventh and twelfth separation distances s11 and s12 may be several mm.

In some embodiments, the first core trench 26o, the second core trench 26p, and the third core trench 26q may have second widths wb, wb′, and wb″. The second widths wb, wb′, and wb″ may differ, but in other embodiments, the second widths wb, wb′, and wb″ may be equal to one another. In some embodiments, each of the second widths wb, wb′, and wb″ may be several mm.

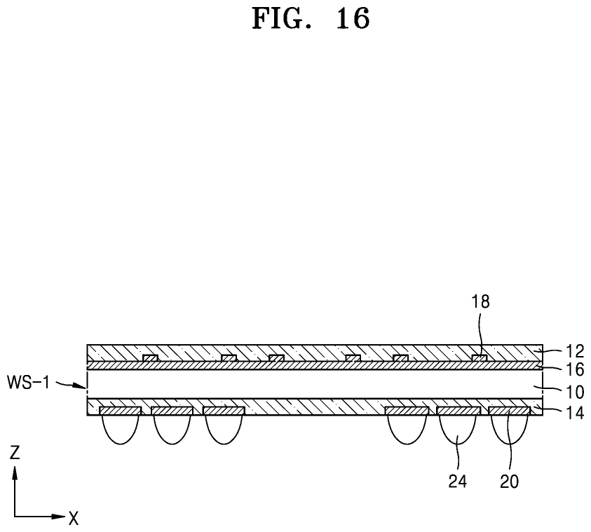

FIGS. 16 to 22 are cross-sectional views for describing a method of manufacturing the flip chip semiconductor package PK1 of FIGS. 1 to 3.

In detail, in FIGS. 16 to 22, descriptions which are the same as or similar to the descriptions of FIGS. 1 to 3 will be briefly given or are omitted. In FIGS. 16 to 22, a first direction (an X direction) may be a direction parallel to a surface of a wiring substrate WS-1, and a third direction (a Z direction) may be a direction vertical to the surface of the wiring substrate WS-1.

Referring to FIG. 16, the wiring substrate WS-1 may be prepared. The wiring substrate WS-1 may be a PCB. The wiring substrate WS-1 may include a core layer 10 and a lower protection layer 14 which is formed on a lower surface of the core layer 10.

The wiring substrate WS-1 may include a wiring layer 16, an upper protection layer 12 (e.g., an upper passivation layer), and internal wiring pads 18. Each of the lower protection layer 14 and the upper protection layer 12 may include a PSR. A plurality of external wiring pads 20 may be spaced apart from one another under the wiring substrate WS-1 and may be insulated from one another by the lower protection layer 14. A plurality of external solder balls 24 may be formed in the external wiring pads 20.

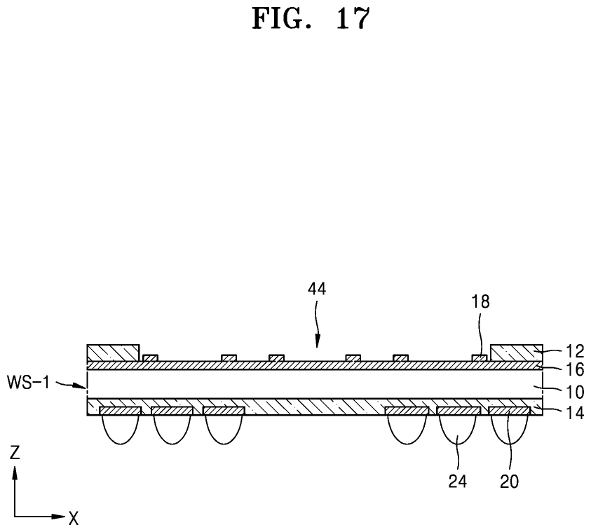

Referring to FIG. 17, an opening region 44 exposing the internal wiring pads 18 and the wiring layer 16 may be formed by patterning the upper protection layer 12. The opening region 44 may be formed in the upper protection layer 12 of the wiring substrate WS-1. The internal wiring pads 18 may be spaced apart from one another in the opening region 44 in or on the wiring layer 16.

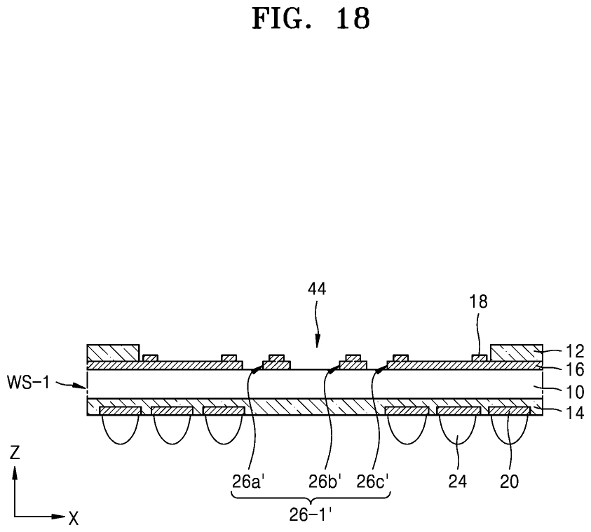

Referring to FIG. 18, a preliminary core trench group 26-1′ may be formed by primarily cutting the wiring layer 16 in the opening region 44. The preliminary cutting may be performed by using a blade. The preliminary core trench group 26-1′ may be formed in the wiring layer 16. A surface of the core layer 10 may be exposed by the preliminary core trench group 26-1′.

The preliminary core trench group 26-1′ may include a first preliminary core trench 26a′, a second preliminary core trench 26b′, and a third preliminary core trench 26c′. The first preliminary core trench 26a′, the second preliminary core trench 26b′, and the third preliminary core trench 26c′ may be spaced apart from one another in the first direction (the X direction). The surface of the core layer 10 may be exposed by the first preliminary core trench 26a′, the second preliminary core trench 26b′, and the third preliminary core trench 26c′.

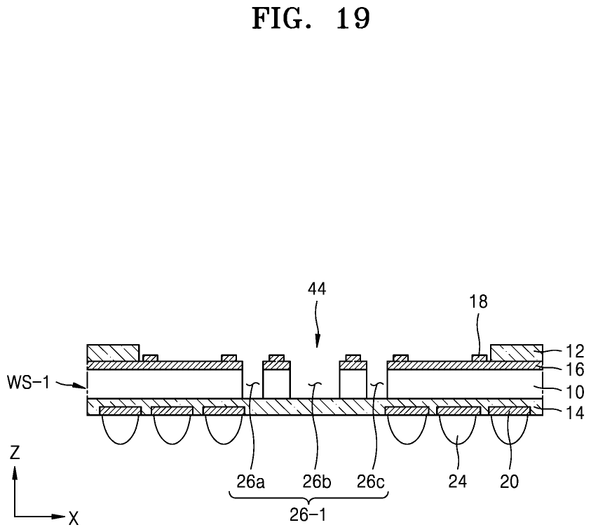

Referring to FIG. 19, a core trench group 26-1 may be formed by secondarily cutting the core layer 10 exposed by a preliminary core trench group (26-1′ of FIG. 18) (i.e., a first preliminary core trench (26a′ of FIG. 18), a second preliminary core trench (26b′ of FIG. 18), and a third preliminary core trench (26c′ of FIG. 18)). The secondary cutting may be performed by using a blade. As described above, the core trench group 26-1 may be incrementally formed in the wiring layer 16 through the primary cutting and the secondary cutting. A surface of the lower protection layer 14 may be exposed by the core trench group 26-1.

The core trench group 26-1 may include a first core trench 26a, a second core trench 26b, and a third core trench 26c. Each of the first core trench 26a, the second core trench 26b, and the third core trench 26c may be spaced apart from one another in the first direction (the X direction). The surface of the lower protection layer 14 may be exposed by the first core trench 26a, the second core trench 26b, and the third core trench 26c.

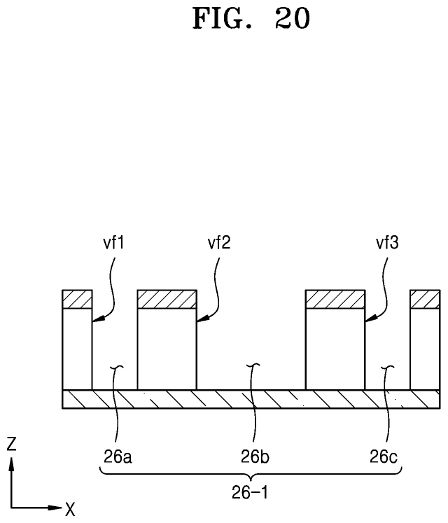

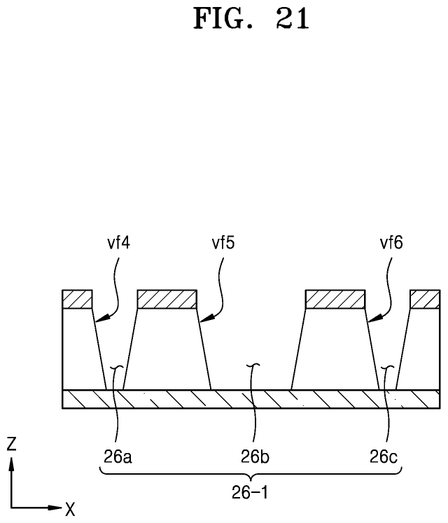

Referring to FIGS. 20 and 21, FIGS. 20 and 21 may be provided for describing sidewall profiles of the first core trench 26a, the second core trench 26b, and the third core trench 26c of the core trench group 26-1 formed by the manufacturing process of FIG. 19.

As illustrated in FIG. 20, sidewalls of the first to third core trenches 26a to 26c may include vertical sidewalls vf1 to vf3 each including an upper portion and a lower portion which are equal to each other. For example, sidewalls of the first to third core trenches 26a to 26c may be vertical sidewalls vf1 to vf3, and respective upper widths and respective lower widths of respective ones of the first to third core trenches 26a to 26c may be equal to each other. As illustrated in FIG. 21, sidewalls of the first to third core trenches 26a to 26c may include inclined sidewalls vf4 to vf6 each having a width which narrows in a direction from an upper portion thereof to a lower portion thereof. For example, sidewalls of the first to third core trenches 26a to 26c may be inclined sidewalls vf4 to vf6, and respective upper widths of respective ones of the first to third core trenches 26a to 26c may be greater than respective lower widths of the respective ones of the first to third core trenches 26a to 26c.

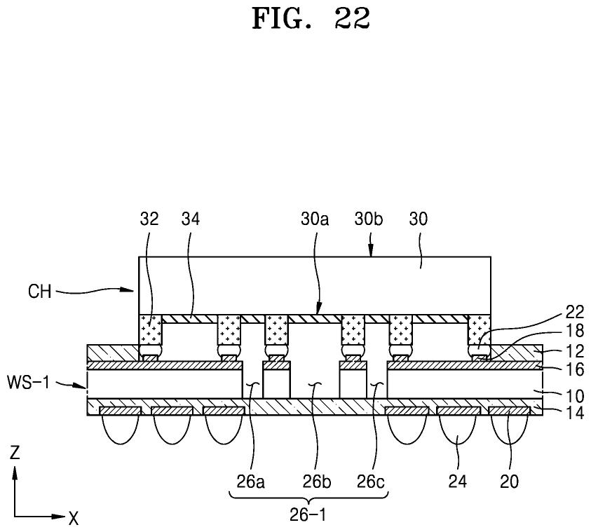

Referring to FIG. 22, a flip chip CH may be mounted on the wiring substrate WS-1. The flip chip CH may include a chip body 30. The chip body 30 may include a first surface 30a and a second surface 30b. The first surface 30a (i.e., an upper surface) may be an active surface where a circuit layer is formed. The flip chip CH may include chip bumps 32 and internal solder balls 22. The internal solder balls 22 may be replaced with internal bumps. The chip bumps 32 may be electrically connected with the internal solder balls 22.

The internal solder balls 22 of the flip chip CH may be mounted on internal wiring pads 18 of the wiring substrate WS-1. The internal solder balls 22 of the flip chip CH may be electrically connected with the internal wiring pads 18 of the wiring substrate WS-1.

Subsequently, a molding layer (36 of FIGS. 1 and 2) sealing the flip chip CH mounted on the wiring substrate WS-1 may be formed. For example, the molding layer 36 may be on the second surface 30b (i.e., a lower surface of the flip chip CH when the flip chip CH is not flipped over), side surfaces of the flip chip CH, and/or the first surface 30a. The molding layer 36 may bury the core trench group 26-1 and may seal the flip chip CH, on the wiring substrate WS-1. For example, the molding layer 36 may extend into the core trench group 26-1. For example, the molding layer 36 may extend into the core trenches 26a to 26c. The molding layer 36 may bury the core trench group 26-1 on the wiring substrate WS-1 and may seal a region between the internal wiring pads 18 and a region between the internal solder balls 22.

As used herein, the words “include/comprise”, “contain”, “have”, and any other variations specify the presence of the stated features, steps, operations, elements, and/or components, but do not preclude the presence or addition of one or more other features, steps, operations, elements, components, and/or groups thereof.

Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the scope of the inventive concept may be defined based on the scope of the following claims.

While the inventive concept has been particularly shown and described with reference to embodiments thereof, it will be understood that various changes in form and details may be made therein without departing from the scope of the following claims.

What is claimed is:

1. A flip chip semiconductor package comprising:
a wiring substrate that includes a core layer and a lower protection layer on a lower surface of the core layer;
a trench group that includes a plurality of trenches spaced apart from one another on the lower protection layer;
a flip chip on the wiring substrate and the trench group; and
a molding layer that is on the flip chip and the wiring substrate, and extends into the plurality of trenches.

2. The flip chip semiconductor package of claim 1, wherein the plurality of trenches extend in a first direction parallel to the wiring substrate from a first region to a second region, the first region being adjacent to a front surface of the flip chip, and the second region being adjacent to a rear surface of the flip chip.

3. The flip chip semiconductor package of claim 2, wherein the plurality of trenches are spaced apart from one another, in a second direction that is perpendicular to the first direction and parallel to the wiring substrate, at a center portion of the wiring substrate.

4. The flip chip semiconductor package of claim 1, wherein ones of the plurality of trenches are between portions of the core layer and extend in a direction perpendicular to the wiring substrate.

5. The flip chip semiconductor package of claim 1, wherein the plurality of trenches comprise vertical sidewalls, and
wherein respective upper widths and respective lower widths of respective ones of the plurality of trenches are equal to each other.

6. The flip chip semiconductor package of claim 1, wherein the plurality of trenches comprise inclined sidewalls, and
wherein respective upper widths of respective ones of the plurality of trenches are greater than respective lower widths of the respective ones of the plurality of trenches.

7. The flip chip semiconductor package of claim 1, wherein respective widths of ones of the plurality of trenches are a combination of being different and equal to one another, and
wherein respective separation distances between adjacent ones of the plurality of trenches are equal to one another.

8. The flip chip semiconductor package of claim 1, wherein the molding layer is on a top surface of the lower protection layer, but does not extend below the lower surface of the core layer.

9. A flip chip semiconductor package comprising:
a wiring substrate that comprises:
a core layer;
a wiring layer on the core layer;
an upper protection layer on the wiring layer;
a lower protection layer on a lower surface of the core layer; and
a plurality of internal wiring pads spaced apart from one another;
a trench group that includes a plurality of trenches spaced apart from one another, wherein the plurality of trenches are on the lower protection layer and at least partially penetrate the wiring layer and the core layer;
a flip chip on the wiring layer, the upper protection layer, and the trench group, the flip chip including a plurality of internal solder balls spaced apart from one another and on the plurality of internal wiring pads; and
a molding layer on the flip chip and the wiring substrate, wherein the molding layer extends into the plurality of trenches, a region between respective ones of the plurality of internal wiring pads, and a region between respective ones of the plurality of internal solder balls.

10. The flip chip semiconductor package of claim 9, further comprising a plurality of external wiring pads spaced apart from one another and insulated from one another by the lower protection layer, and a plurality of external solder balls electrically connected to the plurality of external wiring pads.

11. The flip chip semiconductor package of claim 9, wherein the flip chip further comprises a plurality of chip bumps on the plurality of internal solder balls, and the molding layer extends between respective ones of the plurality of chip bumps and between respective ones of the plurality of internal solder balls without leaving a void therebetween.

12. The flip chip semiconductor package of claim 9, wherein the plurality of internal solder balls comprise a plurality of signal internal solder balls at a center portion of the wiring substrate and a plurality of chip supporting internal solder balls at a peripheral portion of the wiring substrate.

13. The flip chip semiconductor package of claim 9, wherein respective first widths of first ones of the plurality of trenches are equal to one another,
wherein respective second widths of second ones of the plurality of trenches are equal to one another, and
wherein the first widths are different from the second widths.

14. The flip chip semiconductor package of claim 9, wherein the plurality of trenches are spaced apart from one another at a center portion of the wiring substrate, and
wherein respective separation distances between adjacent ones of the plurality of trenches are equal to one another.

15. A flip chip semiconductor package comprising:
a wiring substrate comprising:
a core layer;
a wiring layer on the core layer;
an upper protection layer on the wiring layer;
a lower protection layer on a lower surface of the core layer;
an opening region in the upper protection layer; and
a plurality of internal wiring pads spaced apart from one another in the opening region;
a trench group that includes a plurality of trenches spaced apart from one another, wherein the plurality of trenches are on the lower protection layer and at least partially penetrate the wiring layer and the core layer;
a flip chip on the opening region and the trench group, the flip chip including a plurality of internal solder balls spaced apart from one another and electrically connected to the plurality of internal wiring pads;
a molding layer on the flip chip and the wiring substrate, wherein the molding layer extends into the plurality of trenches, a region between respective ones of the plurality of internal wiring pads, and a region between respective ones of the plurality of internal solder balls;
a plurality of external wiring pads spaced apart from one another and insulated from one another by the lower protection layer; and
a plurality of external solder balls electrically connected to the plurality of external wiring pads.

16. The flip chip semiconductor package of claim 15, wherein the plurality of trenches comprise inclined sidewalls, and respective upper widths of respective ones of the plurality of trenches are greater than respective lower widths of the respective ones of the plurality of trenches.

17. The flip chip semiconductor package of claim 15, wherein the plurality of trenches are spaced apart from one another at a center portion of the wiring substrate, and
wherein the trench group comprises a first trench having a first width and a second trench spaced apart from the first trench and having a second width, the second width being different from or equal to the first width.

18. The flip chip semiconductor package of claim 15, wherein the trench group comprises a first trench having a first width, a second trench spaced apart from the first trench and having a second width, and a third trench spaced apart from the second trench and having a third width, the second width being greater than or equal to each of the first width and the third width.

19. The flip chip semiconductor package of claim 15, wherein the trench group comprises a first trench having a first width, a second trench spaced apart from the first trench and having a second width, a third trench spaced apart from the second trench and having a third width, and a fourth trench spaced apart from the third trench and having a fourth width, each of the first width and the fourth width being greater than each of the second width and the third width.

20. The flip chip semiconductor package of claim 15, wherein the trench group comprises a first trench having a first width, a second trench spaced apart from the first trench and having a second width, a third trench spaced apart from the second trench and having a third width, a fourth trench spaced apart from the third trench and having a fourth width, and a fifth trench spaced apart from the fourth trench and having a fifth width, each of the first width, the third width, and the fifth width being greater than each of the second width and the fourth width.
